(19) United States
(12) Patent Application Publication
(10) Pub. No.: US 2006/0219547 A1
(43) Pub. Date: Oct. 5, 2006

(54) Vertical production of photovoltaic devices

(75) Inventor: John R. Tuttle, Mechanicville, NY (US)

Correspondence Address: HISCOCK & BARCLAY, LLP, 2000 HSBC PLAZA, ROCHESTER, NY, 14604-2404, US

(73) Assignee: Daystar Technologies, Inc.

(21) Appl. No.: 11/272,183

(22) Filed: Nov. 10, 2005

Related U.S. Application Data
(60) Provisional application No. 60/626,843, filed on Nov. 10, 2004.

(51) Int. Cl. C23C 14/00

(52) U.S. Cl. 204/192.12

(57) ABSTRACT

The present invention provides a photovoltaic thin-film solar cell produced by a providing a vertically oriented pallet based substrate to a series of reaction chambers where layers can be sequentially formed on the pallet.

### CROSS-REFERENCE TO RELATED APPLICATIONS

This application claims priority from U.S. Provisional Patent Application Ser. No. 60/626,843, filed Nov. 10, 2004.

### FIELD OF THE INVENTION

The invention disclosed herein relates generally to the manufacture of photovoltaic devices and more specifically to an apparatus for manufacturing thin film the product and method of manufacturing thin-film solar cells using a vertically oriented pallet based system.

### BACKGROUND OF THE INVENTION

The benefits of renewable energy are not fully reflected in the market price. While alternative energy sources such as photovoltaic (PV) cells offer clean, reliable, and renewable energy, high product costs and lack of production reliability have kept these devices from being a viable commercial product. With the demand for energy going up, the world demand for alternatives to present energy sources is increasing.

Although relatively efficient thin-film PV cells can be manufactured in the laboratory, it has proven difficult to commercially scale manufacturing processes with the consistent repeatability and efficiency critical for commercial viability. Moreover, the cost associated with manufacturing is an important factor preventing the broader commercialization of thin-film solar cells. The lack of an efficient thin-film manufacturing process has contributed to the failure of PV cells to effectively replace alternate energy sources in the market.

Thin-film PV cells can be manufactured according to varied designs. In a thin-film PV cell, a thin semiconductor layer of PV materials is deposited on a supporting layer such as glass, metal, or plastic foil. Since thin-film materials have higher light absorptivity than crystalline materials, PV materials are deposited in extremely thin consecutive layers of atoms, molecules, or ions. The typical active area of thin-film PV cells is only a few micrometers thick. The basic photovoltaic stack design exemplifies the typical structure of a PV cell. In that design, the thin-film solar cell comprises a substrate, a barrier layer, a back contact layer, a p-type absorber layer, an n-type junction buffer layer, an intrinsic transparent oxide layer, and a transparent conducting oxide layer. Compounds of copper indium gallium diselenide (CIGS) have the most promise for use in absorber layers in thin-film cells and fit within the classification of copper-indium selenium class, called CIS materials. CIGS films are typically deposited by vacuum-based techniques.

Thin-film manufacturing processes suffer from low yield due to defects in the product that occur during the course of deposition. Specifically, these defects are caused by contamination occurring during processing and materials handling, and the breakage of glass, metal, or plastic substrates. Thus, a process for manufacturing thin-film solar cells that both limits potential contamination during processing and concurrently minimizes substrate breakage is desired in the art.

Currently, cells are manufactured using a multi-step batch process wherein each product piece is transferred between reaction steps. This transfer is bulky and requires the reaction in chambers to be cycled. A typical process consists of a series of individual batch processing chambers, each specifically designed for the formation of various layers in the cell. Problematically, the substrate is transferred from vacuum to air—and back again—several times. Such vacuum breaks may result in contamination of the product. Thus, a process that minimizes vacuum breaks is desired in the art.

While an alternate system uses a series of individual batch processing chambers coupled with a roll-to-roll continuous process for each chamber, the discontinuity of the system and the need to break vacuum continue to be major drawbacks. Additionally, the roll-to-roll process may impose flexing stress on a glass or metal substrate, resulting in fracturing and breakage. Such defects compromise layer cohesiveness and may result in a zero yield.

Also contributing to the low yield in PV cell manufacturing is the requirement of high-temperature deposition processes. High temperatures are generally incompatible with all presently known flexible polyimide or other polymer substrate materials.

For example, U.S. Patent Application 2004/0063320, published by Hollars on Apr. 1, 2004, discloses a general methodology for continuously producing photovoltaic stacks using a roll-to-roll system. As discussed above, this process requires the application of flexing stress to the substrate. This stress potentially results in fractures and breakage where the substrate material is glass or metal. Fractures or breakage reduce high quality stack structures and lower manufacturing yield. Thus, to be a commercially viable process, the disclosed system requires a flexible substrate for the production of the stack. However, no currently known flexible polymer materials can withstand the high-temperature deposition process.

Furthermore, Hollars does not teach any specific apparatus for optimizing the product flow through their continuous system. Horizontal processing is still used as the basic deposition and reaction orientation of the pieces being worked on, and do not employ any scheme for passing multiple processing streams through each or any of the zones.

Therefore, a process that does not impose flexing stress on the substrates, where the substrates can withstand the high-temperature deposition process, is desired in the art. So a process for manufacturing PV work pieces effectively, and capable of large scale production are needed.

### SUMMARY OF THE INVENTION

The present invention provides a photovoltaic produced by providing a vertically oriented product substrate is provided by a continuous backing, a conveyor belts means or by a pallet-based transport means to a series of reaction chambers where sequentially a barrier layer, a back contact layer, an p-type semiconductor layer, alkali materials, an n-type junction buffer layer, an intrinsic transparent oxide layer, a transparent conducting oxide layer and a top metal grid can be formed on the pallet.

A method is further disclosed for forming a photovoltaic device by employing a train of the pallet based holders loaded with work pieces in a vertical orientation and with work piece substrates provided on both the front and the back of each of the pallets so that the controlled reaction chambers produces roughly double the amount of product a single sided pallet would. In this embodiment, a series of pallets are passed at a defined rate through a reactor having a plurality of processing zones, wherein each zone is dedicated to one production step stage of device manufacture.

The specific production steps production that this vertically oriented product train would be processed through might include: a load or isolation zone for substrate preparation; environments for depositing a barrier layer, a back contact layer, a semiconductor layer or layers, and alkali materials; an environment for the thermal treatment of one or more of the previous layers; and an environment for the deposition of: an n-type compound semi-conductor wherein this layer serves as a junction buffer layer, an intrinsic transparent oxide layer, and a conducting transparent oxide layer. In a further embodiment, the process may be adjusted to comprise greater fewer zones in order to fabricate a thin film solar cell having more or fewer layers.

A vertically-oriented pallet type system may be employed where a plurality of work pieces are held as a pallet and a plurality of pallets are processed though a continuous reactor step apparatus. This pallet based system allows continuous processing of smaller work pieces and alternative materials handling steps, such as pallet stacking in intermediate or final steps.

### BRIEF DESCRIPTION OF THE DRAWINGS

FIG. 1 shows an embodiment of a thin-film solar cell produced by the production technology of the present invention.

FIG. 2 schematically represents a reactor for forming solar cells.

FIG. 3 shows a plurality of work piece substrates on a device capable of affixing the substrates onto a carrier, that also has means that allow the pieces to be advanced in a precise fashion through the production apparatus.

FIG. 4 shows a schematic of the pallet used in the present invention populated with a plurality of substrate work pieces.

FIG. 5A shows an embodiment of the processing method wherein two substrates are fed and processed simultaneously by a sequential sputter-evaporate process in accordance with the present invention.

FIG. 5B shows a top view of an embodiment of the processing method wherein two substrates are fed and processed simultaneously by a sequential sputter-evaporate/sputter-evaporate process.

FIG. 6 illustrates another embodiment of the process in accordance with the invention wherein zones further comprise one or more sub-zones.

### DETAILED DESCRIPTION OF THE INVENTION

### General Photovoltaic Stack Designs

The present invention employs a new production apparatus to produce photovoltaic devices. Of course, the particular apparatus will depend upon the specific photovoltaic device design, which can be varied.

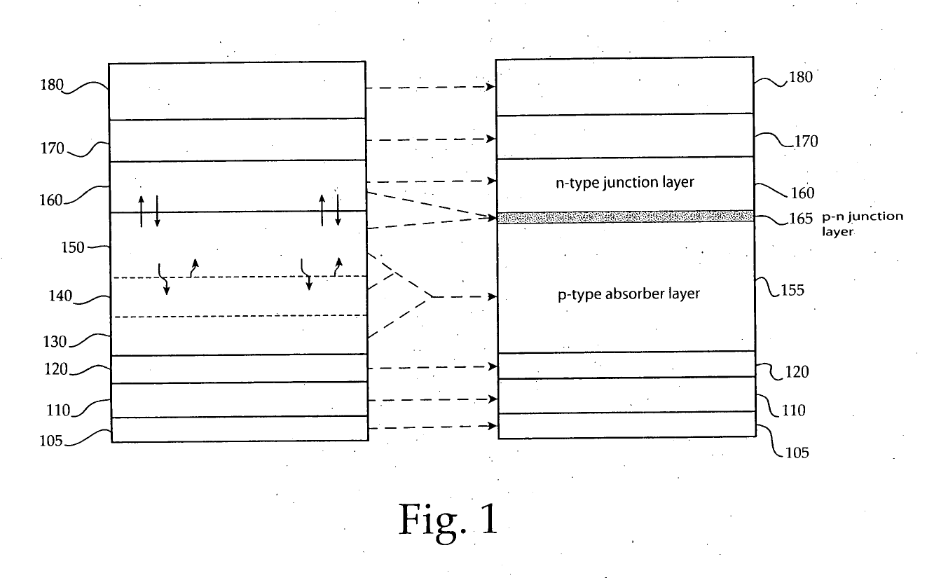

Viewing FIG. 1, all layers are deposited on a substrate 105 which may comprise one of a plurality of functional materials, for example, glass, metal, ceramic, or plastic. Deposited directly on the substrate 105 is a barrier layer 110. The barrier layer 110 comprises a thin conductor or very thin insulating material and serves to block the out diffusion of undesirable elements or compounds from the substrate to the rest of the cell. This barrier layer 110 may comprise chromium, titanium, silicon oxide, titanium nitride and related materials that have the requisite conductivity and durability. The next deposited layer is the back contact layer 120 comprising non-reactive metals such as molybdenum. The next layer is deposited upon the back contact layer 120 and is a p-type semiconductor layer 130 to improve adhesion between an absorber layer 155 and the back contact 120. The p-type semiconductor layer 130 may be a I-III_{a,b}-VI isotype semiconductor, but the preferred composition is Cu:Ga:Se; Cu:Al:Se or Cu:In:Se alloyed with either of the previous compounds.

In this embodiment, the formation of a p-type absorber layer involves the interdiffusion of a number of discrete layers. Ultimately, as seen in FIG. 1, the the p-type semiconductor layers 130 and 150 combine into a single composite layer 155 which serves as the prime absorber of solar energy. In this embodiment, alkali materials 140 are added for the purpose of seeding the growth of subsequent layers as well as increasing the carrier concentration and grain size of the absorber layer 155, thereby increasing the conversion efficiency of the solar cell. Once deposited, the layers are thermally treated at a temperature of about 400° C.-600° C.

After the thermal treatment, the photovoltaic production process is continued by the deposition of an n-type junction buffer layer 160. This layer 160 will ultimately interact with the absorber layer 155 to form the necessary p-n junction 165. A transparent intrinsic oxide layer 170 is deposited next to serve as a hetero-junction with the CIGS absorber. Finally, a conducting transparent oxide layer 180 is deposited to function as the top of the electrode of the cell. This final layer is conductive and may carry current to a grid carrier that allows the current generated to be carried away.

### General Apparatus Configurations

A first embodiment of the invention is an apparatus for manufacturing a photovoltaic device comprising a means for providing a means for presenting the work pieces to the production apparatus where the orientation of the work pieces is vertical. This vertical orientation of the production train allows the work pieces to be disposed on the front and back of the product train and allows an increase in the capacity of the manufacturing apparatus. Surprisingly it has been found that provided the work piece substrates on a vertical axis can be accomplished by employing several factors which include:
Limited substrate height so that reaction chamber technology can be optimized
Adequately isolation of each deposition or reaction chamber from the next
Adequate monitoring and control of the reaction materials and deposition sources
Precise temperature control

It has been found, however, that a system needs a vertical substrate which may employ the positioning of target substrates on both sides of the vertical plane so that a two fold instance in production can be achieved and better and more economical use of the reaction parameters which are so assiduously controlled which involve relatively low pressures and higher temperatures can be more economically achieved.

A plurality of pallets holding multiple substrate pieces may be employed as the means for holding the substrates as the production train, in sequence, is transported through the plurality of reaction zones. These reaction zones include at least a zone capable of providing an environment for deposition of a semiconductor layer, and a zone capable of providing an environment for depositing precursor materials to form a p-type absorber layer.

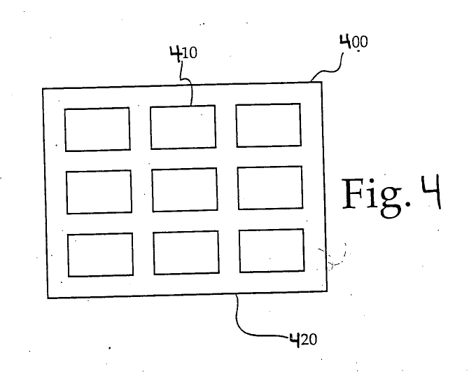

FIG. 4 shows a schematic view of a pallet. The pallet provides a holding basis 400 for a plurality of small PV workpiece substrates 410, or working substrates fixedly attached to the pallet in a pre-determined manner so that the individual work pieces are presented in each treatment chamber in a precise and controllable fashion. The pallet itself is engineered so that the position of the pallet can be precisely determined. The pallet also has a means 420 for allowing attachment to a drive means to advance the pallet through the treatment chamber. Materials of the body of the pallet are chosen so that they are thermally stable and do not interact with the treatment or deposition materials used in the reaction or deposition chamber.

Furthermore, the means for securing the work pieces to the pallet are releasable. In some instances the means for affixing the work piece is magnetic, either because the substrate of the workpiece is itself ferro-magnetic, or with an overlay that hold the individual pieces to the body of the pallet.

In a preferred embodiment, the process may further comprise a substrate that runs back-to-back with the substrate. In this embodiment substrates and are oriented vertically in a back-to-back configuration and run through zones performing identical process operations.

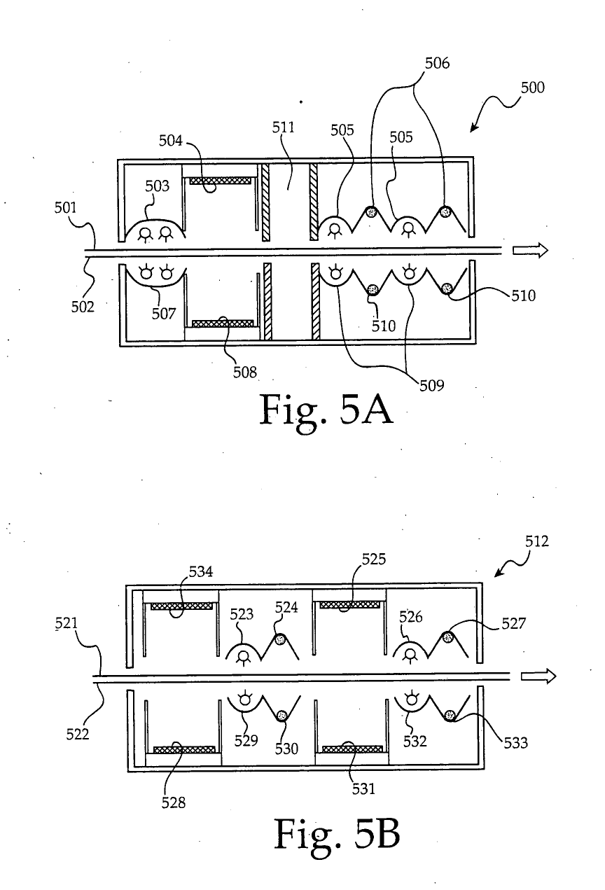

FIG. 5A shows a top illustration of a portion of a reactor 500 processing substrates 501 and 502 in a back-to-back fashion and also illustrates a sequential sputter-evaporate process isolated by zone 511. To achieve back-to-back processing, heat sources 503 for substrate 501 are mirrored as heat sources 507 for substrate 502. Likewise, sputtering source 504, heat sources 505, and evaporative sources 506 for substrate 501 are mirrored for substrate 502 as sputtering source 508, heat sources 509, and evaporative sources 510. FIG. 5A shows this vertical two sided manufacturing process at the top where the two substrates in which the photo devices are being made. Substrates 501 and 502 are processed from left to right through the heating, sputtering and evaporation chambers of a device forming layers to thin films of the PV device. The substrate is passed by sequential heaters 503 and 507 then exposed to sputtering target 503 and 509 with an atmosphere of 1e-3-1e-2 torr. The substrates are then transported through differential pumping chamber at 1e-7-1e-6 torr and then presented to an evaporation deposition chamber where heaters 505 and 509 are used to heat each of the respective substrate 501 and 502 and evaporation sources of gases are provided 506 and 510 respectively.

FIG. 5B shows a top illustration of a portion of a reactor 512 processing substrates 521 and 522 in a back-to-back fashion with a sequential sputter-evaporate/sputter-evaporate process. As in FIG. 5A, sputter sources 534 for substrate 521 are mirrored as sputter sources 528 for substrate 522. Likewise, heat sources 523 and 526, evaporative sources 524 and 527, and sputtering source 525 for substrate 521 are mirrored for substrate 522 as heat sources 529 and 532, evaporative sources 530 and 533, and sputtering source 531. Hence, with the simple duplication of heat and material sources, solar cell production may be effectively doubled within the same machine.

### Alternative Pallet Based Manufacturing Schemes

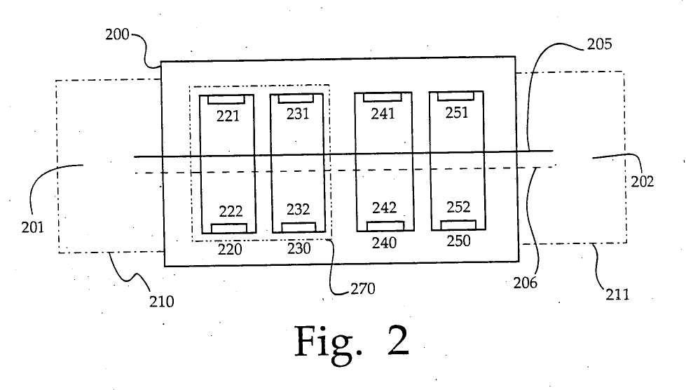

FIG. 2 schematically represents a reactor 200 for forming solar cells. A substrate 205 is fed left to right through the reactor. The reactor 200 includes one or more processing zones, referred to in FIG. 2 as 220, 230, 240 and 250, wherein each processing zone comprises an environment for depositing materials on a substrate 205. The zones are mechanically or operatively linked together within the reactor 200. As used herein, the term environment refers to a profile of conditions for depositing or reacting a material layer or mixture of materials on the substrate 205 while the substrate 205 is in a particular zone.

Each zone is configured according to which layer of the solar cell is being processed. For example, a zone may be configured to perform a sputtering operation, including heat sources and one or more source targets.

Preferably, an elongated substrate 205 is passed through the various processing zones at a controllable rate. It is further contemplated that the substrate 205 may have a translational speed of 0.5 m/min to about 2 m/min. Accordingly, the process internal to each of the zones is preferably tuned to form the desired cross-section given the residence time the material is proximate to a particular source material, given the desired transport speed. Thus, the characteristics of each process, such as material and process choice, temperature, pressure, or sputtering delivery rate, etc., may be chosen to insure that constituent materials are properly delivered given the stack's residence time as determined by the transport or translation speed.

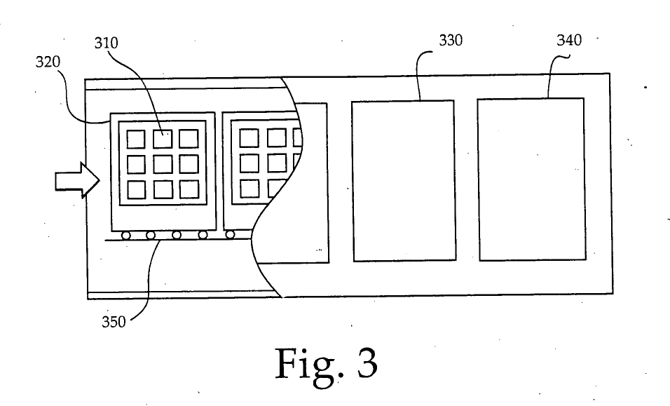

According to the invention, the substrate 205 may be transported through the process in a vertically oriented palletized fashion in a “picture frame” type mount for indexing and transportation through the process, the latter of which is illustrated in FIG. 3. Referring to FIG. 3 one substrate or group of substrates 310 are mounted on a pallet 320 that translates through one or more zones 330 and 340 on track 350. In alternate embodiments the process may further comprise a second substrate or set of substrates placed in a back to back configuration with substrate 310.

It is contemplated that the background pressure within the various zones will range from 10⁻⁶ torr to 10⁻³ torr. Pressures above base-vacuum (10⁻⁶ torr) may be achieved by the addition of a pure gas such as Argon, Nitrogen or Oxygen. Preferably, the rate R is constant resulting in the substrate 205 passing through the reactor 200 from entrance 201 to exit 202 without stopping. It will be appreciated by those of ordinary skill in the art that a solar cell stack may thus be formed in a continuous fashion on the substrate 205, without the need for the substrate 205 to ever stop within the reactor 200.

The reactor in FIG. 2 may further comprise vacuum isolation sub-zones or slit valves configured to isolate adjacent process zones. The vacuum isolation sub-zones or slit valves are provided to facilitate the continuous transport of the substrate between different pressure environments.

The reactor shown in FIG. 2 is a plurality of N-processing zones 220, 230, 240 and 250. However, it should be recognized by one skilled in the art that the reactor may comprise zones 220, 230, 240, 250 . . . N zones. The load/unload zones 210/211 comprise zones that can be isolated from the rest of the reactor and can be open to atmosphere.

In a preferred embodiment, the process may further comprise a substrate 206 that runs back-to-back with substrate 205. In this embodiment substrates 206 and 205 are oriented vertically in a back-to-back configuration and run through zones 220, 230, 240, and 250 performing identical process operations 222/221, 232/231, 242/241 and 252/251.

### SPECIFIC PROCESSING STEPS

Of course, the method steps for producing a particular PV article depends upon the specific design of that article. CIS based PVs will have a different production method than Si based systems. The present invention is not so limited to one PV type and in general any PV could be made with the technology of the invention.

In cases of CIGS, the specific steps might include: loading a substrate through an isolated loading zone or like unit 210. In various embodiments, the isolation zone 210 is contained within the reactor 200. Alternatively, the isolation zone 210 may be attached to the outer portion of the reactor 200. The first processing zone 210 may further comprise a substrate preparation environment to remove any residual imperfections at the atomic level of the surface. The substrate preparation may include: ion beam, deposition, heating, or sputter-etch. These methods are known in the art and will not be discussed further.

A second processing zone may be environment for depositing a barrier layer for substrate impurity isolation, wherein the barrier layer provides an electrically conductive path between the substrate and subsequent layers. In a preferred embodiment, the barrier layer comprises an element such as chromium or titanium delivered by a sputtering process. Preferably, the environment comprises a pressure in the range of about 10⁻³ torr to about 10⁻² torr at ambient temperature.

A third processing zone downstream from the previous zones comprises an environment for the deposition of a metallic layer to serve as a back contact layer. The back contact layer comprises a thickness that provides a conductive path for electrical current. In addition, the back contact layer serves as the first conducting layer of the solar cell stack. The layer may further serve to prevent the diffusion of chemical compounds such as impurities from the substrate to the remainder of the solar cell structure or as a thermal expansion buffer between the substrate layer and the remainder of the solar cell structure. Preferably, the back contact layer comprises molybdenum, however, the back contact layer may comprise other conductive metals such as aluminum, copper or silver.

A fourth zone provides an environment for deposition of a p-type semiconductor layer. As used herein, the p-type semiconductor layer may serve as an epitaxial template for absorber growth. Preferably, the p-type semiconductor layer is an isotype I-IIIVI₂ material, wherein the optical band gap of this material is higher than the average optical band gap of the p-type absorber layer. For example, a semiconductor layer may comprise Cu:Ga:Se; Cu:AI:Se or alloys of Cu:In:Se with either of the previous compounds. Preferably, the materials are delivered by a sputtering process at a background pressure of 10⁻⁶ to 10⁻² torr and at temperatures ranging from ambient up to about 300° C. Preferably, temperatures range from ambient to about 200° C.

A fifth zone, downstream from the previous zones, provides an environment for the deposition of alkali materials to enhance the growth and the electrical performance of a p-type absorber. Preferably, the alkali materials are sputtered, at ambient temperature and a pressure range of about 10⁻⁶ torr to 10⁻² torr. Preferably, the material comprises NaF, Na₂Se, Na₂S or KCl or like compounds wherein the thickness ranges from about 150 nm to about 500 nm.

A sixth zone, also downstream from the previous zones, may comprise an environment for the deposition of additional semiconductor layers comprising precursor materials for the p-type absorber layer. In a preferred embodiment, the sixth zone may further comprise one or more sub-zones for the deposition of the precursor layers. In one embodiment, the layer is formed by first delivering precursor materials in one or more contiguous sub-zones, then reacting the precursor materials into the final p-type absorber in a downstream thermal treatment zone. Thus, especially for CIGS Systems, there may be two material deposition steps and a third thermal treatment step in the format of the layer.

In the precursor delivery zones, the layer of precursor materials is deposited in a wide variety of ways, including evaporation, sputtering, and chemical vapor deposition or combinations thereof Preferably, the precursor material may be delivered at temperatures ranging from about 200° C.-300° C. It is desired that the precursor materials react to form the final p-type absorber as rapidly as possible. As previously discussed, to this end, the precursor layer or layers may be formed as a mixture or a series of thin layers.

A manufacturing device may also have seventh processing zone downstream from previous processing zones for the thermal treatment of one or more of the previous layers. The term multinaries includes binaries, ternaries, and the like. Preferably, thermal treatment reacts previously unreacted elements or multinaries. For example, in one embodiment it is preferred to have Cu, In, Se, and Ga in various combinations and ratios of multinary compounds of elements as the source for deposition on the work piece. The reactive environment includes selenium and sulfur in varying proportions and ranges in temperature from about 400° C. to about 600° C. with or without a background inert gas environment. In various embodiments, processing time may be minimized to one minute or less by optimizing mixing of the precursors. Optimal pressures within the environment depend on whether the environment is reactive or inert. According to the invention, within the thermal treatment zone, the pressures range from about 10⁻⁶ to about 10⁻² torr. However, it should be noted that these ranges depend very much on the reactor design for the stage, the designer of the photovoltaic device and the operational variables of the apparatus as a whole.

The reactor may have an eighth processing zone for the formation of an n-type semiconductor layer or junction partner. The junction layer is selected from the family II-VI, or IIIx VI. For example, the junction layer may comprise ZnO, ZnSe, ZnS, In, Se or In_{N}S deposited by evaporation, sublimation or chemical vapor deposition methodologies. The temperatures range from about 200° C. to about 400° C.

Additionally, the process may also have a ninth zone having an environment for deposition of an intrinsic layer of a transparent oxide, for example ZnO. According to the invention, the intrinsic transparent oxide layer may be deposited by a variety of methods including for example, RF sputtering, CVD or MOCVD.

In various embodiments, the process further has a tenth zone with an environment for the deposition of a transparent conductive oxide layer to serve as the top electrode for the solar cell. In one embodiment for example, aluminum doped ZnO is sputter deposited. Preferably, the environment comprises a temperature of about 200° C. and a pressure of about 5 millitorr. Alternatively, ITO (Indium Tin Oxide) or similar may be used.

In one embodiment, as described above, the reactor may comprise discrete zones wherein each zone corresponds to one layer of photovoltaic device formation. In a preferred embodiment however, zones comprising similar constituents and or environment conditions may be combined thereby reducing the total number of zones in the reactor.

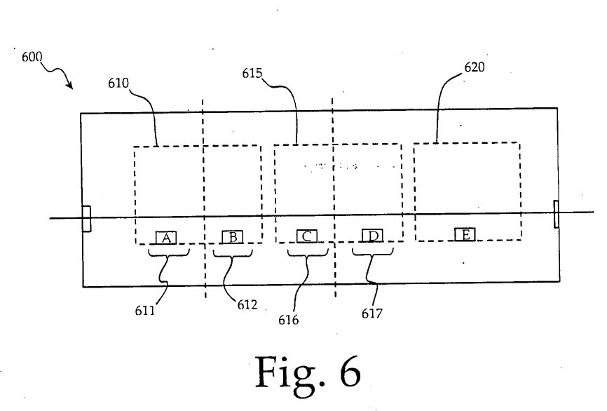

For example, in FIG. 6, zone 610 comprises sub-zones 611 and 612, zone 615 comprises sub-zones 616 and 617, and zone 620 comprises one zone, wherein each zone and sub-zone comprises a predetermined environment. In this example, a material A may be deposited in sub-zone 611 and a different material B may be deposited in sub-zone 612, wherein the environment of sub-zone 612 downstream from material A differs from the environment in sub-zone 611. Thus, the substrate 605 may be subjected to a different temperature or other process profiles while in different regions of the same zone 610. According to this embodiment, the zone may be defined as having a predetermined pressure, and a zone may include one or more regions, sub-zones, or phases therein, with each sub-zone configured to deposit or react a desired material or materials within the same pressure environment.

The substrate 605 may then be passed to chamber 615, where material C is deposited within sub-zone 616, and material D is deposited in sub-zone 617. Finally, the substrate 605 reaches a zone 620, where a single material E is deposited.

As will be appreciated by those of ordinary skill in. the art, the reactor 600 may be described as having a series of zones disposed between the entrance and exit of the reactor along a path defined by the translation of the substrate. Within each zone, one or more constituent environments or sub-zones may be provided to deposit or react a selected target material or materials, resulting in a continuous process for forming a solar cell stack. Once the substrate enters the reactor, the various layers of a solar stack are deposited and formed in a sequential fashion, with each downstream process in succession contributing to the formation of the solar cell stack until a finished thin film solar cell is presented at the exit of the reactor.

While the present technique has been couched in terms of CIGS based photovoltaic stack designs it must be understood that the technique may also be employed for the production of other photovoltaic designs including production of silicon based systems such as those discussed in state of the art. For instance, it would be possible to use to include carbon or germanium atoms in hydrogenated amorphous silicon alloys in order to adjust their optical bandgap. For example, carbon has a larger bandgap than silicon and thus inclusion of carbon in a hydrogenated amorphous silicon alloy increases the alloy's bandgap. Conversely, germanium has a smaller bandgap than silicon and thus inclusion of germanium in a hydrogenated amorphous silicon alloy decreases the alloy's bandgap.

Similarly one could incorporate boron or phosphorus atoms in hydrogenated amorphous silicon alloys in order to adjust their conductive properties. Including boron in a hydrogenated amorphous silicon alloy creates a positively doped conductive region. Conversely, including phosphorus in a hydrogenated amorphous silicon alloy creates a negatively doped conductive region.

Hydrogenated amorphous silicon alloy films are prepared by deposition in a deposition chamber. Heretofore, in preparing hydrogenated amorphous silicon alloys by deposition in a deposition chamber, carbon, germanium, boron or phosphorus have been incorporated into the alloys by including in the deposition gas mixture carbon, germanium, boron or phosphorus containing gases such as methane (CH₄), germane (GeH₄), germanium tetrafluoride (GeF₄), higher order germanes such as digermane (Ge₂ H₆), diborane (B₂ H₆) or phosphine (PH₃). See for example, U.S. Pat. Nos. 4,491,626, 4,142,195, 4,363,828, 4,504,518, 4,344,984, 4,435,445, and 4,394,400. A drawback of this practice, however, is that the way in which the carbon, germanium, boron or phosphorus atoms are incorporated into the hydrogenated amorphous silicon alloy is not controlled. That is, these elements are incorporated into the resulting alloy in a highly random manner thereby increasing the likelihood of undesirable chemical bonds.

Thus, in cases where PV devices are manufactured, and specific and controlled reaction and or deposition conditions are required to produce the films of the PV, the present invention technology will be useful.

What is claimed is:

1. An apparatus for manufacturing a photovoltaic device comprising a means for providing a vertically oriented substrate to a first reaction zone; a plurality of reaction zones including at least a zone capable of providing an environment for deposition of a back contact layer; a zone capable of providing an environment for depositing a p-type semiconductor layer; and a zone capable of providing an environment for depositing a n-type semiconductor layer.

2. The apparatus of claim 1 wherein said means for providing a vertically oriented substrate is a pallet based system and means for transporting pallets through the plurality of reaction zones.

3. The apparatus of claim 1 which further comprises a second means for transporting a vertically oriented substrate to said plurality of reaction zones.

4. A method for manufacturing a photovoltaic device comprising providing a means capable of vertically holding a substrate, in sequence to a plurality of reactor zones wherein said plurality of zones includes at least one zone depositing a p-type semiconductor layer.

5. A method for manufacturing a photovoltaic cell comprising:
a. providing a plurality of vertically disposed substrates;
b. depositing a conductive film on the surface of said plurality of substrates;
c. wherein the conductive film includes a plurality of discrete layers of conductive materials; and
d. depositing an n-type semiconductor layer on an p-type absorber layer forming a p-n junction.

6. The method of claim 5 further depositing at least one p-type semiconductor layer on the conductive film, wherein the p-type semiconductor layer includes a copper indium di-selenide based alloy material.
